(19) United States
(12) Patent Application Publication
(10) Pub. No.: US 2008/0076198 A1
(43) Pub. Date: Mar. 27, 2008

(54) Method of manufacturing light emitting diode package and white light source module

(75) Inventors: Young Sam Park, Seoul (KR); Hun Joo Hahm, Sungnam (KR); Hyung Suk Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/902,233

(22) Filed: Sep. 20, 2007

(30) Foreign Application Priority Data
Sep. 21, 2006 (KR) 10-2006-0091878

(51) Int. Cl. H01L 21/00; H01J 9/02

(52) U.S. Cl. 438/27; 445/46; 257/E33.059

(57) ABSTRACT

A method of manufacturing a light emitting diode package, the method including: forming a resin mold encapsulating a light emitting diode chip; and forming a phosphor thin film on a surface of the resin mold by applying a phosphor-containing coating material on the surface of the resin mold.

### CROSS-REFERENCE TO RELATED APPLICATIONS

This application claims the priority of Korean Patent Application No. 2006-91878 filed on Sep. 21, 2006, in the Korean Intellectual Property Office, the disclosure of which is incorporated herein by reference.

### BACKGROUND OF THE INVENTION

1. Field of the Invention

The present invention relates to a method of manufacturing a light emitting diode (LED) package and a white light source module, and more particularly, to a method of manufacturing an LED package by spray coating and a method of manufacturing a white light source module using the same.

2. Description of the Related Art

Of late, a light emitting diode (LED) is used as a light source of a variety of colors. An increasing demand for high-output and high-brightness LEDs such as white LEDs for illumination has led to vigorous studies for enhancing performance and reliability of LED packages. LED products can be improved in performance when equipped with the LED chips having superior optical efficiency and the LED packages which are efficient in extracting light, excellent in color purity and less heat-damaged.

In general, a white LED package can be manufactured by utilizing a suitable LED chip and a phosphor. For example, to obtain the white LED package, a blue LED chip mounted on a package body may be encapsulated by a mold resin having a yellow phosphor dispersed therein. Here, when the blue LED chip emits light with a wavelength of 460 nm, the yellow phosphor in the mold resin emits light with a wavelength of 545 nm. Then the light of two different wavelengths is combined together to output white light.

This LED package can be beneficially used as a light source of a white light source module such as a backlight unit. For example, a plurality of white LED packages may be arrayed on a board to manufacture a light source of backlight units (BLUs) of liquid crystal displays (LCDs). The LED-based BLUs can perform local dimming and is environment-friendly.

FIGS. 1A and 1B are cross-sectional views illustrating an example of a conventional LED package. Referring to FIG. 1A, the LED package 10 includes an LED chip 15 coated with a thin film phosphor 17 and a resin mold 18 encapsulating the LED chip. A phosphor material in the phosphor film 17 is excited by light, e.g., blue light or ultraviolet rays emitted from the LED chip 15 to emit light of different wavelengths, such as green, yellow and blue light. The light emitted from the phosphor may be used alone or in conjunction with light emitted from the LED chip 15 to produce white light.

To manufacture this LED package 10, the LED chip 15 is coated with the thin film phosphor 17 by an appropriate method such as capillary electrophoresis. Thereafter, the coated LED chip 15 is encapsulated by a resin material to form a lens-shaped resin mold 18. This lens-shaped resin mold 18 may be formed, for example, by a die having a lens-shaped indentation.

However, in the LED package 10 described above, the LED chip 15 emits much less light due to the phosphor thin film 17 surrounding the LED chip 15, accordingly rendered unsuitable for a high-brightness LED.

Referring to FIG. 1B, an LED package 20 includes an LED chip 15 and a lens-shaped resin mold 28 encapsulating the LED chip 15. A plurality of phosphors 3 are dispersed in the resin mold 28. The LED chip, e.g., blue LED chip and the phosphors, e.g., yellow phosphors are adequately combined together to produce white light. The lens-shaped resin mold 28 may be formed, for example, by a die having a lens-shaped indentation. Yet, in the LED package 20, due to the plurality of phosphors present in an optical path of light emitted from the LED chip 15, the light emitted from the LED chip 15 is scattered by the phosphors, thereby reducing overall light amount.

In an alterative method, after a transparent lens-shaped resin mold (inner lens) is formed, a phosphor/silicone shell may be formed in the resin mold by an additional die process. However, this method does not sufficiently suppress light amount loss caused by the phosphor/silicone shell, while not producing the shell with a uniform thickness. Also, in the die process for the phosphor/silicone shell, the phosphor/silicone shell may be formed in an undesired portion, such as a portion between the LED packages in manufacturing a plurality of LED packages on a board. This portion requires high reflectivity and thus it may be not desirable that the phosphor or transparent resin material is applied thereon. U.S Patent Publication No. US2006/0105485 A1 discloses a phosphor/silicone shell formed using a die.

### SUMMARY OF THE INVENTION

An aspect of the present invention provides a method of manufacturing a light emitting diode (LED) package capable of reducing light loss amount and enhancing optical extraction efficiency.

An aspect of the present invention also provides a method of manufacturing a white light source module having an LED package capable of increasing brightness and optical efficiency.

According to an aspect of the present invention, there is provided a method of manufacturing an LED package, the method including: forming a resin mold encapsulating an LED chip; and forming a phosphor thin film on a surface of the resin mold by applying a phosphor-containing coating material on the surface of the resin mold.

The forming a phosphor thin film may include: spraying the phosphor-containing coating material onto the surface of the resin mold in a conical swirl spray pattern. This spray coating of a swirl mode ensures only a desired portion of the phosphor thin film to be coated precisely to a uniform thickness.

The phosphor-containing coating material may include: a phosphor material for converting a wavelength of light emitted from the LED chip and a liquid resin material having the phosphor material dispersed therein. The liquid resin material may be one selected from silicone, epoxy, hybrid silicone, and hybrid epoxy.

The resin mold has a lens shape. Particularly, the resin mold may be shaped as an upwardly convex lens such as a hemispherical lens.

According to another aspect of the present invention, there is provided a method of manufacturing a white light source module, the method including: mounting a plurality of LED chips on a circuit board; forming a resin mold encapsulating each of the LED chips; and forming a phosphor thin film on a surface of the resin mold by applying a coating material containing a phosphor on the surface of the resin mold by spray coating.

The LED chip may be a blue LED chip and the phosphor may be a yellow phosphor. The LED chip may be a blue LED chip and the phosphor may be a mixture of green and red phosphors. Also, the LED chip may be an ultraviolet ray LED chip and the phosphor may be a mixture of blue, green and red phosphors.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A and 1B are cross-sectional views illustrating a conventional LED package;

FIG. 2 is a cross-sectional view illustrating an LED package manufactured by a method according to an exemplary embodiment of the invention;

FIG. 3 is a schematic view illustrating a spray process in a manufacturing method according to an exemplary embodiment of the invention; and

FIGS. 4 through 8 are cross-sectional views for explaining a method of manufacturing a white light source module according to an exemplary embodiment of the invention.

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

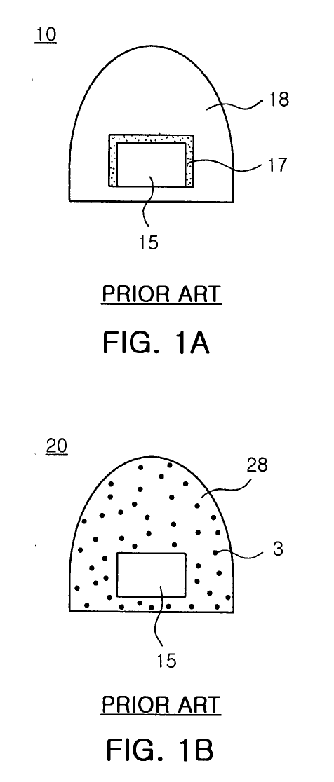

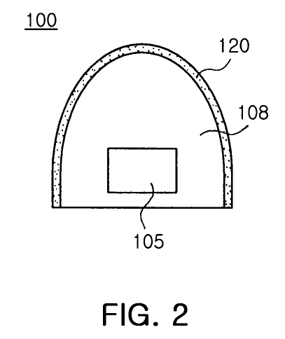

FIG. 2 is a schematic cross-sectional view illustrating a light emitting diode (LED) package manufactured according to an exemplary embodiment of the invention. Referring to FIG. 1, the LED package 100 includes an LED chip 105, a transparent resin mold 108 encapsulating the LED chip 105 and a phosphor thin film 120 coated on the resin mold 108. The resin mold 108 may be formed in the shape of a convex lens such as a hemispherical lens. The phosphor thin film 120 converts a wavelength of light emitted from the LED chip 105. The phosphor thin film 120 is formed by spray coating as described later. The spray coating allows the phosphor thin film 120 to have a very small and uniform thickness, e.g., 0.5 to 3 mm.

Light emitted from the LED chip 105, i.e., primary light passes through the transparent resin mold 108 and then at least a portion of the primary light is converted into secondary light of a different wavelength by the phosphor thin film 120. The secondary light may be used alone or in combination with the primary light to produce white light. For example, the LED chip 105 and the phosphor thin film 120 may be configured as one of “a blue LED chip and a yellow phosphor thin film”, “a blue LED chip and a thin film formed of a mixture of green and red phosphors”, and “an ultraviolet ray LED chip and a thin film formed of a mixture of blue, green and red phosphors” to produce white light.

The LED package 100 as described above does not experience internal scattering of light resulting from the phosphor on an optical path thereof, thereby prevented from decrease in light amount and improved in brightness. Also, the phosphor is less deteriorated by heat from the LED chip due to its location outside the resin mold 108. Particularly, the resin mold 108 may be formed of a resin material having a reflectivity as high as possible. The resin mold 108 having a reflectivity closer to that of the LED chip 105 enhances optical extraction efficiency of the LED package 100.

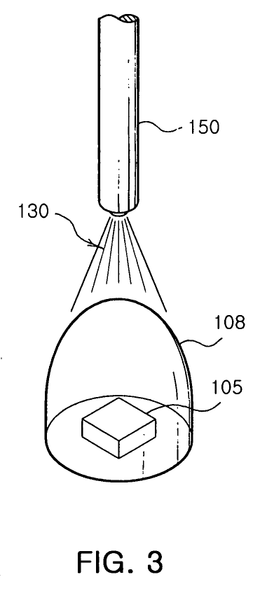

Next, a method of manufacturing the LED package will be described with reference to FIGS. 2 and 3. First, the LED chip 105 is mounted on an adequate submount, e.g., circuit board (not shown) and the resin mold 108 is formed to encapsulate the LED chip 105 using a transparent resin material. As shown in FIG. 2, the resin mold 108 may have, but not limited to, an upwardly convex lens shape. The transparent resin material for the resin mold 108 may adopt one of epoxy, silicone, hybrid silicone and hybrid epoxy.

Thereafter, as shown in FIG. 3, a phosphor-containing coating material is applied on a surface of the resin mold 108 by spray coating. The spray coating has been in general use for painting. With the spray coating, the coating material is sprayed onto an object to be coated using a spray nozzle. This spray coating allows formation of a coating film with a relatively small thickness. A spray jet 130 of the phosphor-containing coating material from the spray nozzle 150 is deposited on the surface of the resin mold 108, thereby forming the phosphor thin film 120 on the surface of the resin mold 108. The phosphor-containing coating material may employ a phosphor-containing liquid resin obtained by dispersing phosphor powder in a liquid resin such as epoxy, silicone, hybrid epoxy and hybrid silicone.

More particularly, the coating material may be spray-coated in a conical swirling spray pattern. This swirl mode of spray coating ensures only a desired portion to be coated precisely to a very small, e.g., 500 μm and uniform thickness. Also, the swirl mode of spray coating assures an edge with a big morphological change to be relatively easily coated to a uniform thickness.

To perform the swirl mode of spray coating, a pressurized air is sprayed in a direction inclined with respect to a bead discharged from an end of the spray nozzle 150. With the pressurized air sprayed, the coating material is sprayed or atomized and the atomized coating material forms a conical spray pattern. Here, the conical spray pattern may have a width adjusted according to a spray angle and spray amount of the pressurized air. In addition, the pressurized air sprayed allows the atomized coating material to swirl within the conical spray pattern. This accordingly prevents the coating material from departing from the conical spray pattern and enables the coating material to be precisely coated on a desired area or portion.

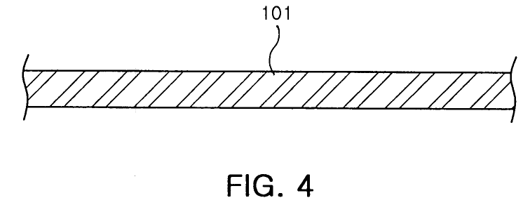

The phosphor thin film formed by the spray coating offers following additional advantages over a conventional process of forming a phosphor/silicone shell using a die. First, to form the shell by the conventional die process, a resin should be injected into the die at a certain amount or more, thus requiring a great amount of resin and phosphor to be consumed. However, the spray coating enables an extremely small amount of the resin to be consumed. Second, in the case of formation of the shell by the conventional die process, an additional new die for shell formation should be fabricated every time the resin mold (lens) is changed in shape. This incurs additional costs and wastes time considerably. In contrast, the spray coating hardly entails additional costs and time waste. Third, in a case where a white light source module, e.g., backlight unit is manufactured by the spray coating (see FIGS. 4 through 7), the spray coating may be directly carried out on a surface of the resin mold after formation of the resin mold on the board, thereby streamlining an overall process of manufacturing the light source module.

FIGS. 4 through 7 illustrate a method of manufacturing a white light source module according to an exemplary embodiment of the invention.

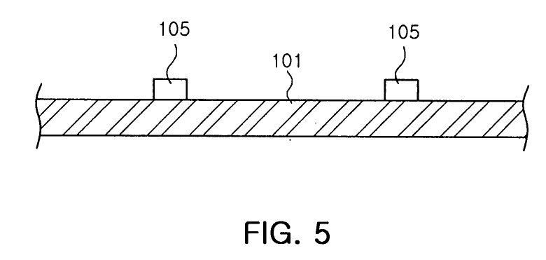

First, a circuit board 101 having a circuit pattern on a top surface thereof is prepared as shown in FIG. 4 and a plurality of LED chips 105 are mounted on the circuit board 101 as shown in FIG. 5. Here, the LED chips 105 are directly mounted on the circuit board 101 without an additional package body to produce an LED light source module of a chip on board type as described later.

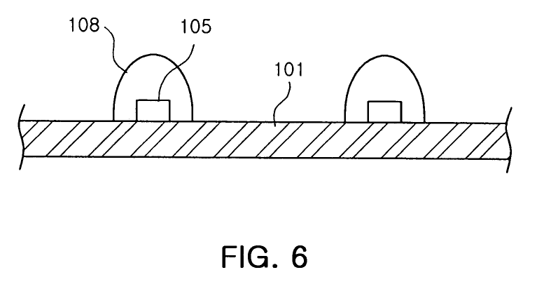

Subsequently, as shown in FIG. 6, each of the LED chips 105 is encapsulated by a transparent resin material to form a resin mold 108 in the shape of an upwardly convex lens, e.g., hemispherical lens. The resin mold may be formed by a die having a lens-shaped indentation. A phosphor-containing resin material is filled in the die and the LED chip 105 is placed into the resin material. Then the resin material is cured to obtain the resin mold 108 of a desired lens shape. However, the present invention is not limited to formation of the resin mold using the die. For example, a liquid resin may be dotted using a dispenser to be cured, thereby forming the resin mold.

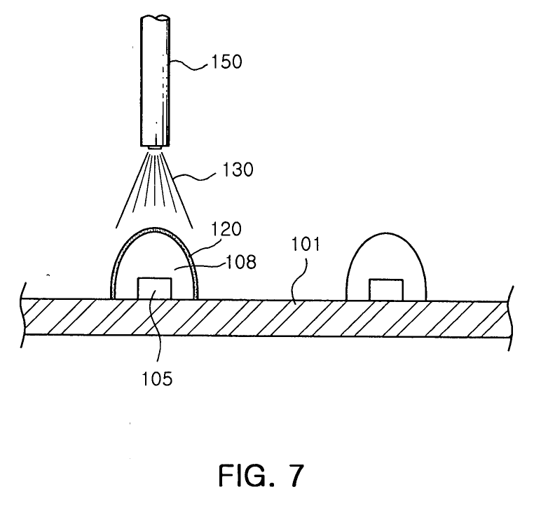

Thereafter, as shown in FIG. 7, a phosphor-containing coating material is coated on a surface of the resin mold 108 by the spray coating described above. Particularly, the coating material is spray-coated by a swirl mode featuring a conical swirling spray pattern. This accordingly produces a phosphor thin film 120 coated to a very small and uniform thickness of several mm or less. Notably, the swirl mode of spray coating easily ensures a phosphor thin film to be locally coated only on a desired area, e.g., surface of the resin mold. This effectively prevents the phosphor film from being formed unnecessarily on a portion of the board between LED packages. Such a portion between the packages may require a high reflectivity. Therefore, the phosphor film or resin film coated on the unnecessary portion of the board may degrade optical efficiency of the white light source module.

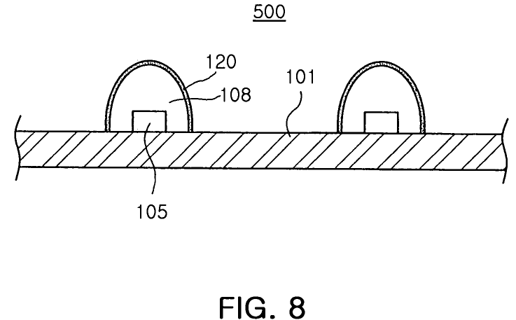

The phosphor thin film 120 coated by spray coating is dried to obtain a white light source module 500 as shown in FIG. 8. The white light source module 500 may be beneficially utilized as a white surface or line light source such as a light source of a backlight unit used in a liquid crystal display. Especially, the white light source module 500 of the present embodiment is an LED light source module of a chip on board (COB) type, and the LED chip 105 is directly mounted on the circuit board 101 without an additional board or package body. The LED light source module of the COB type reduces package costs and ensures each of the LED chips to attain a greater view angle. Also, the view angle of the LED chip may be varied according to a shape of the resin mold 108.

To obtain white light from the LED light source module 500 shown in FIG. 8, suitable phosphors may be combined together according to a wavelength of the LED chip. For example, a blue LED chip may be employed as the LED chip 105 and a yellow phosphor may be employed as a phosphor material in the phosphor thin film 120. To assure a better color rendering index, the blue LED chip and a mixture of the green and red phosphors may be employed. Alternatively, an ultraviolet ray LED chip may be utilized as the LED chip 105 and a mixture of blue, green and red phosphors may be used as a phosphor material in the phosphor thin film 120.

As set forth above, according to exemplary embodiments of the invention, light amount is prevented from decreasing due to internal scattering to enhance overall light extraction efficiency of an overall LED package. Also, a phosphor thin film may be coated uniformly on a resin mold by spray coating. In addition, a view angle of an LED chip may be varied by a shape of the resin mold.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a light emitting diode package, the method comprising:
forming a resin mold encapsulating a light emitting diode chip; and
forming a phosphor thin film on a surface of the resin mold by applying a phosphor-containing coating material on the surface of the resin mold.

2. The method of claim 1, wherein the forming a phosphor thin film comprises: spraying the phosphor-containing coating material onto the surface of the resin mold in a conical swirl spray pattern.

3. The method of claim 1, wherein the phosphor-containing coating material comprises a phosphor material for converting a wavelength of light emitted from the light emitting diode chip and a liquid resin material having the phosphor material dispersed therein.

4. The method of claim 3, wherein the liquid resin material is one selected from silicone, epoxy, hybrid silicone, and hybrid epoxy.

5. The method of claim 1, wherein the resin mold has a lens shape.

6. A method of manufacturing a white light source module, the method comprising:
mounting a plurality of light emitting diode chips on a circuit board;
forming a resin mold encapsulating each of the light emitting diode chips; and
forming a phosphor thin film on a surface of the resin mold by applying a coating material containing a phosphor on the surface of the resin mold by spray coating.

7. The method of claim 6, wherein the forming a phosphor thin film comprises spraying the phosphor-containing coating material onto the surface of the resin mold in a conical swirl spray pattern.

8. The method of claim 6, wherein the phosphor-containing coating material comprises a phosphor material for converting a wavelength of light emitted from the light emitting diode chip and a liquid resin material having the phosphor material dispersed therein.

9. The method of claim 8, wherein the liquid resin material may be one selected from silicone, epoxy, hybrid silicone, and hybrid epoxy.

10. The method of claim 6, wherein the resin mold has a lens shape.

11. The method of claim 6, wherein the light emitting diode chip is a blue light emitting diode chip and the phosphor is a yellow phosphor.

12. The method of claim 6, wherein the light emitting diode chip is a blue light emitting diode chip and the phosphor is a mixture of green and red phosphors.

13. The method of claim 6, wherein the light emitting diode chip is an ultraviolet ray light emitting diode chip and the phosphor is a mixture of blue, green and red phosphors.
